(19) United States
(12) Patent Application Publication
(10) Pub. No.: US 2022/0223709 A1
(43) Pub. Date: Jul. 14, 2022

(54) METAL GATE STRUCTURE AND MANUFACTURING METHOD THEREOF

(71) Applicant: SHANGHAI IC R&D CENTER CO., LTD., Shanghai (CN)

(72) Inventor: Xiaoyu LIU, Shanghai (CN)

(21) Appl. No.: 17/295,062

(22) PCT Filed: Aug. 7, 2019
(86) PCT No.: PCT/CN2019/099580

§ 371 Date: Jan. 23, 2022

(30) Foreign Application Priority Data
Nov. 26, 2018 (CN) 201811415934.6

(51) Int. Cl. H01L 29/49; H01L 29/40; H01L 21/285

(52) U.S. Cl. CPC H01L 29/4966; H01L 29/4236; H01L 21/28568; H01L 29/401

(57) ABSTRACT

The present invention discloses a metal gate structure, comprising from inside to outside: a metal electrode layer, a bonding layer surrounding the metal electrode layer, a first diffusion barrier layer and a work function layer, a second diffusion barrier layer within the first diffusion barrier layer; wherein, the second diffusion barrier layer is a composite barrier layer structure comprising a metal layer and a metal oxide layer within the metal layer. The present invention also discloses a manufacturing method for a metal gate structure, comprising: depositing a work function layer in a trench of a substrate by a conventional metal gate process; form a first diffusion barrier layer on the work function layer; depositing a metal layer on the first diffusion barrier layer; forming a metal oxide layer on the surface of the metal layer, which form a second diffusion barrier layer; depositing a bonding layer on the second diffusion barrier layer; depositing material of a metal electrode layer on the bonding layer to form a metal gate. The present invention effectively solves a problem of electrode metal diffusion.

### TECHNICAL FIELD

The disclosure relates to the technical field of integrated circuit manufacturing technology, in particular to a metal gate structure capable of controlling metal diffusion and a manufacturing method thereof.

### BACKGROUND

Metal oxide semiconductor field effect transistor (MOSFET) is a most important device structure in integrated circuits at present. With decreasing device size, more and more new technologies are introduced into device manufacturing processes.

At the 32 nm process node, Intel first introduced a metal gate process to replace an original polysilicon gate process. Compared with a polysilicon gate, resistance of a metal gate is smaller, which improves a speed of signal transmission, and there is no polysilicon depletion phenomenon of the polysilicon gate in the metal gate, which is beneficial to reduce MOS capacitance of the device and improve the performance of the device.

However, a problem of electrode metal aluminum diffusion exists in the metal gate. A common process solution is to deposit a barrier layer (such as a titanium nitride and tantalum nitride layer) to block Al diffusion after depositing a work function layer; subsequently, metal titanium is deposited as a bonding layer to prevent Al peeling. FIG. 1 shows an existing metal gate film structure, which includes from inside to outside: a metal aluminum electrode 14, a metal titanium bonding layer 13, a diffusion barrier layer 12 of tantalum nitride and titanium nitride, and a work function layer 11.

Under actual process conditions, with decreasing process characteristic size, size of an opening used to deposit the barrier layer and the electrode metal in the metal gate process also becomes smaller and smaller, which requires the thickness of the barrier layer must be reduced accordingly, thus barrier ability is greatly reduced, and aluminum is more likely to diffuse into the work function layer, so as to affect the performance of the device. Meanwhile, due to physical vapor deposition (PVD) is generally weak in filling sidewalls of a trench, the diffusion is especially obvious on the sidewalls of the metal gate.

Therefore, in 14 nm and below processes, tungsten is usually used instead of aluminum as an electrode material. Since melting point of tungsten is very high, there is almost no diffusion problem. But its disadvantage is that resistivity of tungsten is about twice that of aluminum, which significantly increases the resistance as the electrode material, and it is easy to produce holes when filling by tungsten, which affects the yield of the device.

### SUMMARY

The technical problem to be solved by the present invention is to provide a metal gate structure and a manufacturing method thereof to solve a problem of electrode metal diffusion.

In order to achieve the above object, the present invention provides a metal gate structure, comprising from inside to outside: a metal electrode layer, a bonding layer surrounding the metal electrode layer, a first diffusion barrier layer and a work function layer; and further comprising: a second diffusion barrier layer within the first diffusion barrier layer; wherein, the second diffusion barrier layer is a composite barrier layer structure comprising a metal layer and a metal oxide layer within the metal layer.

Further, the material of the metal oxide layer is oxide of the metal layer material.

Further, the metal oxide layer is an oxide layer of the metal layer formed directly on the inner surface of the metal layer.

Further, the materials of the metal layer and the bonding layer are titanium.

Further, the material of the metal electrode layer is aluminum, the material of the first diffusion barrier layer is a composite layer of tantalum nitride and titanium nitride, and the material of the work function layer is a composite layer of tantalum nitride and titanium nitride, or a composite layer of tantalum nitride and titanium aluminum alloy.

To achieve the above objective, the present invention also provides a manufacturing method of a metal gate structure, comprising:

step S01, depositing a work function layer in a trench of a substrate by a conventional metal gate process;

step S02, depositing tantalum nitride and titanium nitride on the work function layer to form a first diffusion barrier layer;

step S03, depositing a metal layer on the first diffusion barrier layer;

step S04, forming a metal oxide layer on the surface of the metal layer, which form a second diffusion barrier layer together with the metal layer;

step S05, depositing a bonding layer on the second diffusion barrier layer;

step S06, depositing material of a metal electrode layer on the bonding layer to form a metal gate.

Further, in step S04, the method of forming the metal oxide layer comprises:

exposing the substrate directly to air to form a natural oxide layer on the surface of the metal layer as the metal oxide layer; or,

sending the substrate to a degassing pretreatment process chamber of a physical vapor deposition machine, and inputting oxygen to form an oxide layer as the metal oxide layer; or,

sending the substrate to a furnace tube equipment for surface oxidation, so as to form an oxide layer as the metal oxide layer.

Further, the deposition thickness of the metal layer is one-third to two-thirds of a thickness of a bonding layer under a standard process condition in a conventional metal gate process, the deposition thickness of the bonding layer is a bonding layer thickness under the standard process condition in the conventional metal gate process minus the metal layer thickness.

Further, the materials of the metal layer and the bonding layer are titanium.

Further, the material of the metal electrode layer is aluminum, the material of the first diffusion barrier layer is a composite layer of tantalum nitride and titanium nitride, and the material of the work function layer is a composite layer of tantalum nitride and titanium nitride, or a composite layer of tantalum nitride and titanium aluminum alloy.

Beneficial effects of the present invention are that, compared with the existing metal gate process, the present invention introduces the metal oxide layer in the metal layer of the metal gate, which is applied together with the metal layer as the second diffusion barrier layer, base on the original first diffusion barrier layer, so as to effectively increase the barrier ability of the diffusion barrier layer to the diffusion of the metal electrode, improve the performance of the device, and reduce a risk of device failure. Moreover, in the present invention, the operation of oxidizing the metal thin film layer is additionally performed after the work function layer is formed, which avoids work function drift caused by passivating of the work function layer or before the formation of the work function layer, and also effectively prevents the electrode metal from diffusing into the work function layer, so as to ensure that the device performance is not affected. Meanwhile, the oxide layer is used as the diffusion barrier layer, the total thickness of the original film layer will not be increased, the size of the opening filled with the metal electrode is not reduced, so as to effectively avoid a problem that the metal electrode is difficult to fill.

### BRIEF DESCRIPTION OF THE DRAWINGS

FIG. 1 is a schematic diagram of an existing metal gate structure.

FIG. 2 is a schematic diagram of a metal gate structure according to a preferred embodiment of the present invention.

FIG. 3 is a flowchart of a manufacturing method of a metal gate structure of the present invention.

FIG. 4 to FIG. 9 are schematic diagrams of process steps for manufacturing a metal gate structure according to the method of FIG. 3.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the disclosure as recited in the appended claims.

It is to be understood that “first”, “second” and similar terms used in the specification and claims are not to represent any sequence, number or importance but only to distinguish different parts. Likewise, similar terms such as “a” or “an” also do not represent a number limit but represent “at least one”. It is also to be understood that term “and/or” used in the present disclosure refers to and includes one or any or all possible combinations of multiple associated items that are listed.

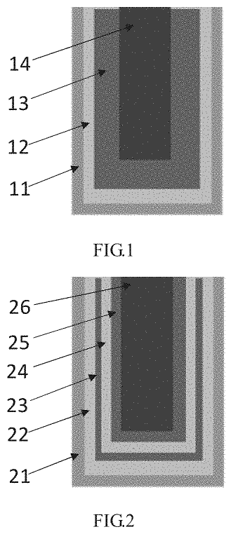

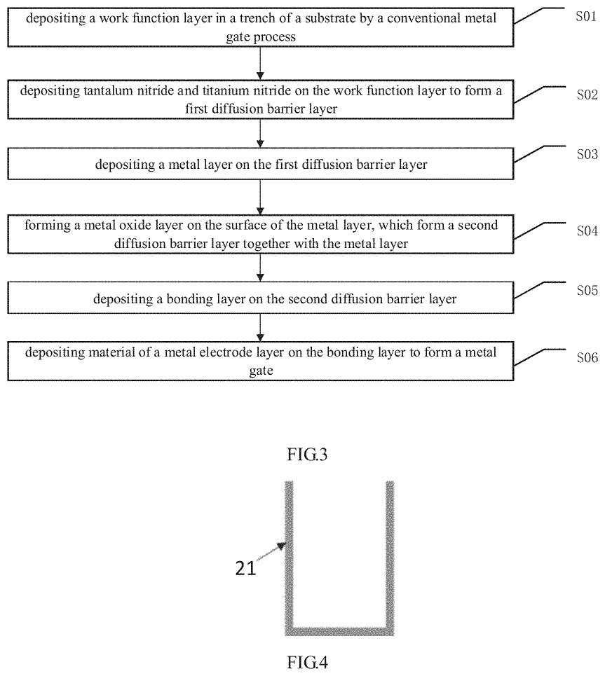

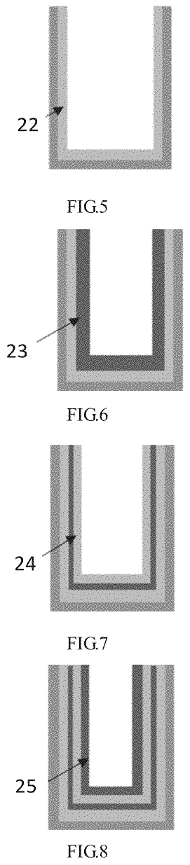

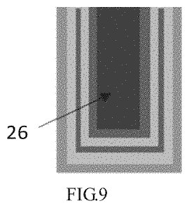

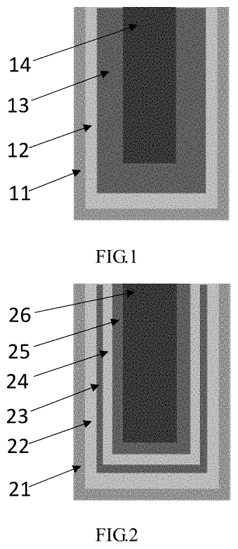

Please refer to FIG. 2. A metal gate structure of the present invention can be provided on a silicon wafer substrate (not shown in FIG. 2), for example, it can be a trench gate structure. The present invention is not limited to this. The metal gate structure of the present invention comprises from outside to inside: a work function layer 21 deposited in a trench on a substrate, a first diffusion barrier layer 22 deposited on the work function layer 21, and a second diffusion barrier layer 23 and 24 deposited on the first diffusion barrier the layer 22, a bonding layer 25 deposited on the second diffusion barrier layer 23 and 24, and a metal electrode layer 26 deposited on the bonding layer 25. Wherein, the bonding layer 25, the second diffusion barrier layer 23 and 24, the first diffusion barrier layer 22 and the work function layer 21 can surround the metal electrode layer 26 from periphery and bottom, and the metal electrode layer 26 can be lead out from the upper end. The upper surface of the metal gate structure can be planarized.

Please refer to FIG. 2. In the above-mentioned metal gate structure, the second diffusion barrier layer 23 and 24 can be a composite barrier layer 23 and 24 comprising a metal layer 23 and a metal oxide layer 24 set within the metal layer 23.

As an optional embodiment, the material of the metal oxide layer 24 can be an oxide of the material of the metal layer 23.

As another optional embodiment, the metal oxide layer 24 can also be an oxide layer of the metal layer 23 formed directly on the inner surface of the metal layer 23.

The material of the metal layer 23 can be titanium, etc. The present invention is not limited to this.

The material of the bonding layer 25 can be titanium, etc. The present invention is not limited to this. Wherein, the material of the metal layer 23 and the material of the bonding layer 25 can be same metal or different metals.

As other optional embodiments, the material of the metal electrode layer 26 can be aluminum, etc. The material of the first diffusion barrier layer 22 can be a composite layer of tantalum nitride and titanium nitride. For PMOS, the material of the work function layer 21 can be a material of a composite layer which generally comprises tantalum nitride and titanium nitride from bottom to top; for NMOS, the material of the work function layer 21 can be a material of a composite layer which generally comprises tantalum nitride and titanium aluminum alloy from bottom to top.

Hereinafter, a manufacturing method for a metal gate structure of the present invention will be described in detail through specific embodiments and drawings.

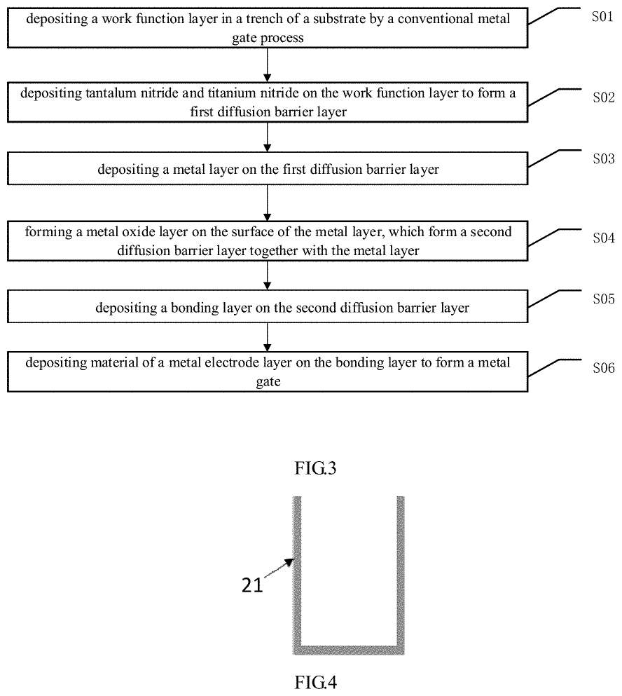

Please refer to FIG. 3 and FIG. 4 to FIG. 9. The manufacturing method for the metal gate structure of the present invention can be used to manufacture the above-mentioned metal gate structure, and comprises the following steps:

Step S01, depositing a work function layer in a trench of a substrate by a conventional metal gate process.

Please refer to FIG. 4. A silicon wafer substrate (not shown in FIG. 4) can be used, and the trench is first formed on the substrate through the conventional metal gate process. Wherein, the trench can be a trench-shaped opening formed after removing a dummy gate.

Then, a PVD or an ALD process can be used to deposit the work function layer 21 in the trench. Wherein, when PMOS devices need to be fabricated, materials of tantalum nitride and titanium nitride can be deposited from bottom to top to form the work function layer 21, which is formed by the material of the composite layer comprised of tantalum nitride and titanium nitride; when NMOS devices need to be fabricated, materials of tantalum nitride and titanium aluminum alloy can be deposited from bottom to top to form the work function layer 21, which is formed by the material of the composite layer comprised tantalum nitride and titanium aluminum alloy.

Step S02, depositing tantalum nitride and titanium nitride on the work function layer to form a first diffusion barrier layer.

Please refer to FIG. 5. Then, a PVD or an ALD process can be used to deposit a conventional barrier layer (the first diffusion barrier layer 22) on the work function layer 21. During deposition, a tantalum nitride layer and a titanium nitride layer are generally included from bottom to top, which are used to prevent electrode (aluminum) diffusion. If an electrode (aluminum) diffuses into the work function layer 21, it will cause a shift of a work function, thus affect turn-on voltage of MOS tubes. Wherein, for atomic layer deposition (ALD), film thickness is usually adjusted by numbers of cycle; for physical vapor deposition (PVD), the film thickness is usually adjusted by sputtering power and deposition time.

Step S03, depositing a metal layer on the first diffusion barrier layer.

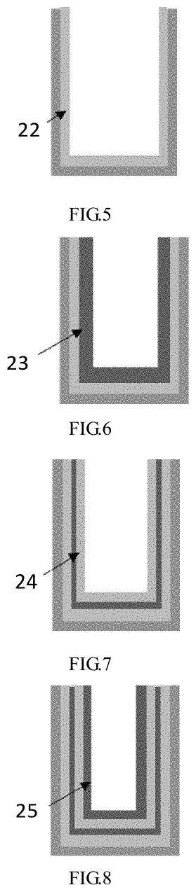

Please refer to FIG. 6. Then, a PVD process can be used to deposit a metal layer 23 on the first diffusion barrier layer 22. For example, the metal layer 23 can be titanium. Wherein, the thickness of titanium deposited is one-third to two-thirds under a standard process condition (that is, one-third to two-thirds of a thickness of an original titanium bonding layer).

Step S04, forming a metal oxide layer on the surface of the metal layer, which form a second diffusion barrier layer together with the metal layer.

Please refer to FIG. 7. Then, a dense oxide layer (the metal oxide layer 24) is formed on the surface of the metal layer (titanium) 23 deposited in step S03.

Similar to aluminum, titanium is very easy to oxidize and oxidized to form an oxide layer which is very dense, so as to prevent further oxidation of bulk metal. Therefore, by controlling process conditions, a dense titanium oxide with a thickness of 1 nm to 2 nm can be formed on the surface of the titanium formed in step S03.

The oxide layer 24 can be formed in a number of ways:

The first method is to directly expose the silicon wafer substrate to air for 1 min˜30 min to form the natural oxide layer 24.

The second method is to send the silicon wafer substrate to a degassing pretreatment process chamber of a physical vapor deposition machine, input oxygen of 1 sccm˜50 sccm, and stay at a temperature of 100° C.˜300° C. for 5 s˜60 s to form the oxide layer 24. That is, a plasma oxidation process is used.

The third method is to send the silicon wafer substrate to a furnace tube equipment for surface oxidation to form the oxide layer 24. That is to use a thermal oxidation process.

Step S05, depositing a bonding layer on the second diffusion barrier layer.

Please refer to FIG. 8. Then, a titanium layer is deposited as the bonding layer 25. Wherein, the thickness of the titanium bonding layer 25 is a thickness of the original bonding layer under the standard process condition minus the thickness of the titanium metal layer 23 deposited in step S03, so as to ensure that the total thickness of the titanium deposited in step S03, titanium oxide deposited in step SO4 and titanium deposited in step S05 is basically equal to the thickness of the titanium bonding layer under the standard process condition, thus the size of the opening filled with the metal electrode is not reduced.

Step S06, depositing material of a metal electrode layer on the bonding layer to form a metal gate.

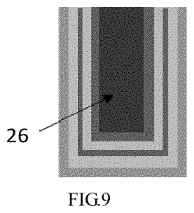

Please refer to FIG. 9. Then, an aluminum reflow process of a physical vapor deposition process can be used to deposit the metal electrode layer 26, for example, to deposit the metal electrode aluminum.

Finally, planarization can be performed by a chemical mechanical polishing process to form a complete metal gate structure as shown in FIG. 2.

In summary, compared with the existing metal gate structure in FIG. 1, the present invention introduces the titanium oxide layer in the metal layer of the metal gate, which is applied together with the titanium layer as the metal barrier layer (the second diffusion barrier layer), based on the original first diffusion barrier layer, so as to effectively increase the barrier ability of the entire diffusion barrier layer to the aluminum diffusion of the metal electrode, improve the performance of the device, and reduce a risk of device failure. Moreover, in the present invention, the operation of oxidizing TiN is additionally performed to TiN in the work function after both the P-type work function layer and the N-type work function layer are formed. The present invention can not only achieve a purpose of preventing the electrode metal from diffusing, but also effectively preventing the electrode metal from diffusing into the N-type work function. As we all know, TiN is a main P-type work function layer of a metal gate process currently, if TiN is passivated or a barrier layer below is passivated, the work function of the device will be significantly changed. The oxidation treatment of the present invention hardly affects the work function before filling the electrode material away from the work function layer. Meanwhile, the oxide layer is used as the diffusion barrier layer, the total thickness of the original film layer is not increased, thus the size of the opening filled with the metal electrode is not reduced, so as to effectively avoid a problem that the metal electrode is difficult to fill.

It will be appreciated that the disclosure is not limited to the exact construction that has been described above and illustrated in the accompanying drawings, and that various modifications and changes can be made without departing from the scope thereof. It is intended that the scope of the disclosure only be limited by the appended claims.

1. A metal gate structure, comprising from inside to outside: a metal electrode layer, a bonding layer surrounding the metal electrode layer, a first diffusion barrier layer and a work function layer; and further comprising: a second diffusion barrier layer within the first diffusion barrier layer; wherein, the second diffusion barrier layer is a composite barrier layer structure comprising a metal layer and a metal oxide layer within the metal layer.

2. The metal gate structure of claim 1, wherein the material of the metal oxide layer is oxide of the metal layer material.

3. The metal gate structure of claim 1, wherein the metal oxide layer is an oxide layer of the metal layer formed directly on the inner surface of the metal layer.

4. The metal gate structure of claim 1, wherein the materials of the metal layer and the bonding layer are titanium.

5. The metal gate structure of claim 1, wherein the material of the metal electrode layer is aluminum, the material of the first diffusion barrier layer is a composite layer of tantalum nitride and titanium nitride, and the material of the work function layer is a composite layer of tantalum nitride and titanium nitride, or a composite layer of tantalum nitride and titanium aluminum alloy.

6. A manufacturing method for a metal gate structure, comprising:
step S01, depositing a work function layer in a trench of a substrate by a conventional metal gate process;
step S02, depositing tantalum nitride and titanium nitride on the work function layer to form a first diffusion barrier layer;
step S03, depositing a metal layer on the first diffusion barrier layer;
step S04, forming a metal oxide layer on the surface of the metal layer, which form a second diffusion barrier layer together with the metal layer;
step S05, depositing a bonding layer on the second diffusion barrier layer;
step S06, depositing material of a metal electrode layer on the bonding layer to form a metal gate.

7. The manufacturing method of claim 6, wherein in step S04, the method of forming the metal oxide layer comprises:
exposing the substrate directly to air to form a natural oxide layer on the surface of the metal layer as the metal oxide layer; or,
sending the substrate to a degassing pretreatment process chamber of a physical vapor deposition machine, and inputting oxygen to form an oxide layer as the metal oxide layer; or,
sending the substrate to a furnace tube equipment for surface oxidation, so as to form an oxide layer as the metal oxide layer.

8. The manufacturing method of claim 6, wherein the deposition thickness of the metal layer is one-third to two-thirds of a thickness of a bonding layer under a standard process condition in a conventional metal gate process, the deposition thickness of the bonding layer is a bonding layer thickness under the standard process condition in the conventional metal gate process minus the metal layer thickness.

9. The manufacturing method of claim 6, wherein the materials of the metal layer and the bonding layer are titanium.

10. The manufacturing method of claim 6, wherein the material of the metal electrode layer is aluminum, the material of the first diffusion barrier layer is a composite layer of tantalum nitride and titanium nitride, and the material of the work function layer is a composite layer of tantalum nitride and titanium nitride, or a composite layer of tantalum nitride and titanium aluminum alloy

11. The manufacturing method of claim 7, wherein the materials of the metal layer and the bonding layer are titanium.
